(19) United States
(12) Patent Application Publication
(10) Pub. No.: US 2019/0047902 A1
(43) Pub. Date: Feb. 14, 2019

(54) SEALED DEVICES COMPRISING UV-ABSORBING FILMS

(71) Applicant: CORNING INCORPORATED, CORNING, NY (US)

(72) Inventors: Heather Debra Boek, Corning, NY (US); Nadja Teresia Lonnroth, Corning, NY (US); Mark Alejandro Quesada, Horseheads, NY (US); Alexander Mikhailovich Streltsov, Corning, NY (US); Mark Owen Weller, Painted Post, NY (US)

(21) Appl. No.: 16/085,779

(22) PCT Filed: Mar. 16, 2017
(86) PCT No.: PCT/US2017/022674

§ 371 Date: Sep. 17, 2018

Related U.S. Application Data
(60) Provisional application No. 62/309,614, filed on Mar. 17, 2016.

(51) Int. Cl. C03C 4/08; H01L 51/52; C03C 27/06; B29C 65/16; G02F 1/161; H01L 33/56; H01S 5/022

(52) U.S. Cl. CPC C03C 4/085; H01L 51/5246; C03C 27/06; H01S 5/022; G02F 1/161; H01L 33/56; B29C 65/1638

(57) ABSTRACT

Disclosed herein are sealed devices comprising a first substrate, a second substrate, an inorganic film between the first and second substrates, and at least one bond between the first and second substrates. The inorganic film can comprise about 10-80 mol % B₂O₃, about 5-60 mol % Bi₂O₃, and about 0-70 mol % ZnO. Methods for sealing devices using such an inorganic film are also disclosed herein, as well as display and electronic components comprising such sealed devices.

### CROSS-REFERENCE TO RELATED APPLICATION

This application claims the benefit of priority under 35 U.S.C. § 119 of U.S. Provisional Application Ser. No. 62/309,614 filed on Mar. 17, 2016, the content of which is relied upon and incorporated herein by reference in its entirety.

### FIELD OF THE DISCLOSURE

The disclosure relates generally to sealed devices and electronic and display components comprising such sealed devices, and more particularly to sealed glass devices comprising transparent seals and display devices comprising the same.

### BACKGROUND

Sealed packages and casings are increasingly popular for application to electronics and other devices that may benefit from a hermetic environment for sustained operation. Exemplary devices which may benefit from hermetic packaging include displays, such as televisions, comprising light emitting diodes (LEDs), organic light emitting diodes (OLEDs), and/or quantum dots (QDs). Other exemplary devices include, for instance, sensors, optical devices, 3D inkjet printers, solid-state lighting sources, and photovoltaic structures, to name a few.

Traditional processes for making sealed devices can be challenging due to harsh processing conditions. Glass, ceramic, and/or glass-ceramic substrates can be sealed by placing the substrates in a furnace, with or without an epoxy or other sealing material. However, the furnace typically operates at high processing temperatures which are unsuitable for many devices, such as OLEDs and QDs. Glass substrates can also be sealed using glass frit, e.g., by placing glass frit between the substrates and heating the frit with a laser or other heat source to seal the package. However, glass frit may have drawbacks such as requiring higher processing temperatures unsuitable for heat-sensitive devices, producing undesirable gases upon sealing, patterning complexities (e.g., forming a frame around a device to be sealed), sealing defects, and/or undesirably low tensile strength and/or shear strain.

Frit-based sealants include glass particles that may be mixed with a filler material having a similar particle size and a negative coefficient of thermal expansion (CTE). Negative CTE inorganic fillers, such as cordierite, silicate, eucryptite, vanadate, and tungstate fillers, may be added to the glass frit to lower the mismatch of thermal expansion coefficients between the substrates and the glass frit. The combined powders can be mixed with an organic solvent and/or binder, which can adjust the rheological viscosity of the resulting paste for dispensing purposes. To join two substrates, a glass frit paste can be applied to sealing surfaces on one or both of the substrates. The frit-coated substrate(s) may be initially subjected to an organic burn-out step at relatively low temperature to remove any organic components. Two substrates to be joined can then be assembled and/or mated along respective sealing surfaces and the glass frit may be melted to form a glass seal.

Traditional frit seals can have the additional drawback of lacking transparency. For instance, the negative CTE inorganic fillers used in the glass frit may be incorporated into the seal upon melting and can result in a barrier layer that is non-transparent, e.g., opaque. In some instances, the frit seal may not be optically clear, e.g., may be colored. These deficiencies are particularly detrimental in the case of sealed packages used for emitting, transmitting, converting, extracting, diffusing, and/or scattering light. For example, opaque seals may block light transmission, whereas seals that are not optically clear may undesirably distort light as it passes through the sealed region. For these reasons, frit-based sealants are often applied around the perimeter of a substrate, e.g., in a frame around an item to be sealed or only at the edges even if no item is sealed in the package. Nonetheless, the material at the edges can still undesirably distort or reduce light transmission in some configurations.

Sputtering of glass compositions to form a sealing layer may also be performed as an alternative to frit sealing, but current sputtering methods may have undesirably low processing rates. For example, depending on the durability of the glass composition, the sputtering power and/or temperature may be lowered to prevent undesirable reactions, phase changes, and/or compositional changes. Moreover, many glass sealing compositions may comprise fluorine (e.g., SnF₂), which can necessitate time-consuming and/or costly environmental precautions during processing.

Accordingly, it would be advantageous to provide methods for laser sealing substrates, which may, among other advantages, increase seal transparency, strength, and/or hermeticity, decrease manufacturing cost and/or complexity, and/or increase production rate and/or yield. It would also be advantageous to provide sealed devices for displays and other electronic devices that can have improved light transmission and/or decreased distortion. It would furthermore be desirable to provide low melting temperature glass sealing compositions that are able to withstand high power sputtering conditions and/or that are environmentally friendly. The resulting sealed devices can themselves be used as components in display or other electronic devices or can be used to protect a wide array of electronics and other components, such as light emitting structures or color converting elements, e.g., laser diodes (LDs), LEDs, OLEDs, and/or QDs.

### SUMMARY

The disclosure relates, in various embodiments, to methods for sealing devices, the methods comprising forming an inorganic film over a surface of a first substrate; positioning a second substrate in contact with the inorganic film; and bonding the first and second substrates by locally heating the inorganic film with laser radiation having a predetermined wavelength, wherein the inorganic film comprises from about 10-80 mol % B₂O₃, from about 5-60 mol % Bi₂O₃, and from about 0-70 mol % ZnO.

In various embodiments, the inorganic film, first substrate, and/or second substrate may have an optical transmittance of at least about 80% in the visible spectrum (e.g., about 420-750 nm). In other embodiments, the inorganic film may have an optical absorbance of at least 15% at a predetermined wavelength of the laser radiation, such as UV and NIR wavelengths. According to certain embodiments, the inorganic film is substantially free of inorganic fillers and/or binders and/or one or more elements selected from the group consisting of Fe, Cr, Mn, Co, Ni, Cu, Na, La, C, Sn, Cd, and V. For example, the inorganic film may comprise a non-frit glass composition.

The inorganic film may, in non-limiting embodiments, have a composition comprising about 40-75 mol % B₂O₃, about 20-45 mol % Bi₂O₃, and about 0-40 mol % ZnO. In other embodiments the inorganic film may have a composition comprising about 10-80 mol % B₂O₃, about 5-60 mol % Bi₂O₃, about 0-70 mol % ZnO, and at least one oxide of cerium, niobium, tungsten, iron, and/or vanadium. According to further embodiments, the inorganic film may have a glass transition temperature (Tg) ranging from about 300-500° C. In still further embodiments, the inorganic film may have a coefficient of thermal expansion (CTE) of about 4-12×10⁻⁶/° C. over a temperature range from 25-300° C., which may be the same or different than a CTE of the first and/or second substrate. In yet further embodiments, the inorganic film may have a UV cutoff at about 380 nm or less.

In some embodiments, a second inorganic film may also be formed on a surface of the second substrate. According to additional embodiments, a device or workpiece to be protected may be positioned between the first and second substrates. The inorganic film may be formed over substantially all of the surface of the first substrate or may be formed around a perimeter of the device to be protected.

Also disclosed herein are sealed devices comprising an inorganic film formed over a surface of a first substrate; a second substrate in contact with the inorganic film; and a bond formed between the inorganic film and the first and second substrates, wherein the inorganic film comprises from about 10-80 mol % B₂O₃, from about 5-60 mol % Bi₂O₃, and from about 0-70 mol % ZnO. Display and electronic components comprising such sealed devices are also disclosed herein.

According to certain embodiments, at least one of the first and second substrates may comprise a glass, glass-ceramic, ceramic, or metal. In non-limiting embodiments, both the first and second substrates can comprise a glass or glass-ceramic. A thickness of the inorganic film can range, for example, from about 10 nm to about 2 μm. According to various embodiments, the sealed device can further comprise a device positioned between the first and second substrates. The device may be chosen, for instance, from light emitting diodes, organic light emitting diodes, conductive leads, semiconductor chips, ITO leads, patterned electrodes, continuous electrodes, quantum dot materials, phosphors, and combinations thereof.

Additional features and advantages of the disclosure will be set forth in the detailed description which follows, and in part will be readily apparent to those skilled in the art from that description or recognized by practicing the methods as described herein, including the detailed description which follows, the claims, as well as the appended drawings.

It is to be understood that both the foregoing general description and the following detailed description present various embodiments of the disclosure, and are intended to provide an overview or framework for understanding the nature and character of the claims. The accompanying drawings are included to provide a further understanding of the disclosure, and are incorporated into and constitute a part of this specification. The drawings illustrate various embodiments of the disclosure and together with the description serve to explain the principles and operations of the disclosure.

### BRIEF DESCRIPTION OF THE DRAWINGS

The following detailed description can be further understood when read in conjunction with the following drawings, in which:

FIG. 1A is a side view of a sealed device comprising two substrates and an inorganic film;

FIG. 1B is a top view of an article undergoing an exemplary sealing process;

FIG. 2 is a B₂O₃—ZnO—Bi₂O₃ ternary phase diagram illustrating exemplary compositions according to embodiments of the disclosure;

FIG. 3 is a B₂O₃—ZnO—Bi₂O₃ ternary phase diagram illustrating glass transition temperatures for exemplary compositions according to embodiments of the disclosure;

FIG. 4 is a B₂O₃—ZnO—Bi₂O₃ ternary phase diagram illustrating coefficients of thermal expansion for exemplary compositions according to embodiments of the disclosure;

FIGS. 5A-C illustrate transmittance spectra for exemplary compositions according to embodiments of the disclosure;

FIG. 6 is a plot of weld line width as a function of laser scan speed according to embodiments of the disclosure;

FIGS. 7A-C are images of glass welds made according to embodiments of the disclosure;

FIG. 8A-B illustrate transmittance spectra for exemplary compositions according to embodiments of the disclosure;

FIG. 9 is a plot of weld line width as a function of laser scan speed according to embodiments of the disclosure;

FIGS. 10A-C are images of glass welds made according to embodiments of the disclosure.

### DETAILED DESCRIPTION

Devices

Disclosed herein are sealed devices comprising an inorganic film formed over a surface of a first substrate; a second substrate in contact with the inorganic film; and a bond formed between the inorganic film and the first and second substrates, wherein the inorganic film comprises from about 10-80 mol % B₂O₃, from about 5-60 mol % Bi₂O₃, and from about 0-70 mol % ZnO. Display and electronic components comprising such sealed devices are also disclosed herein.

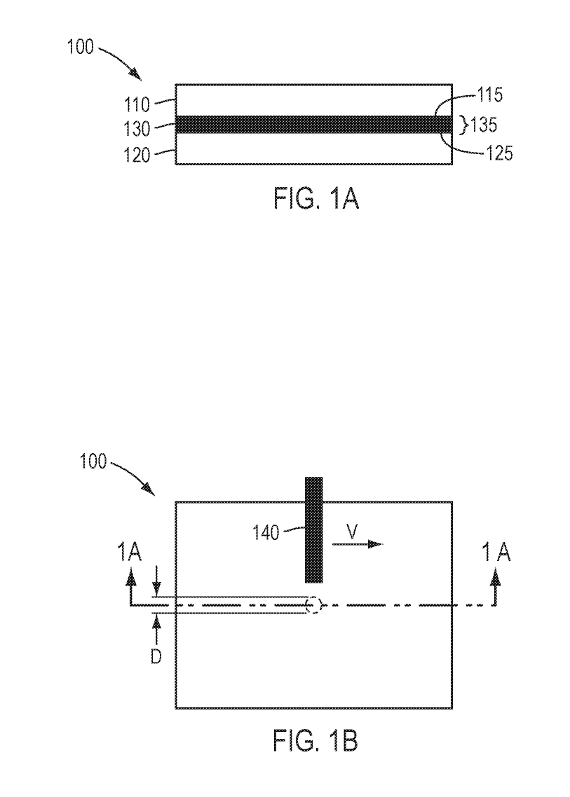

FIG. 1A depicts a side view of a sealed device 100 comprising a first substrate 110 having a first surface 115 and a second substrate 120 having a second surface 125. An inorganic film 130 can be disposed between the first substrate 110 and second substrate 120, to form a sealing interface 135. The sealing interface 135 is referred to herein as the point of contact between the first surface 115 of the first substrate 110 and the second surface 125 of the second substrate 120 with the inorganic film 130, e.g., the meeting of the surfaces to be joined by the weld or bond.

In some embodiments, the inorganic film 130 can be formed over all, substantially all, or a portion of the first surface 115 and/or the second surface 125. Although not shown in FIG. 1A, a device, layer, or other element can be provided on the first or second surfaces 115 or 125, and can either be in contact with (e.g., abutting or overlaid with) the inorganic film 130 or, in other embodiments, the inorganic film 130 can be arranged around the device, layer, or element (e.g., in a frame or other configuration disposed around the perimeter of the device). In further embodiments, one or both of the first and second substrates 110, 120 can comprise one or more cavities (not shown) in which a device or element may be deposited.

The first and second substrates 110, 120 may comprise any material known in the art for use in a sealed device, such as sealed packages for LDs, LEDs, OLEDs, QDs, phosphors, transparent conductive oxide (TCO) layers, semiconductors, electrodes, and conductive leads, to name a few. Exemplary sealable substrates include glasses, glass-ceramics, ceramics, polymers, metals, metal oxides, and the like. Non-limiting examples of glass substrates can include, for instance, from soda-lime silicate, aluminosilicate, alkali-aluminosilicate, alkaline earth-aluminosilicate, borosilicate, alkali-borosilicate, alkaline earth-borosilicate, alum inoborosilicate, alkali-alum inoborosilicate, alkaline earth-alum inoborosilicate, and other suitable glasses, which may optionally be chemically strengthened and/or thermally tempered. Other exemplary substrates can include gallium nitride, quartz, silica, calcium fluoride, magnesium fluoride, sapphire, tungsten, molybdenum, copper, and indium tin oxide. According to some embodiments, at least one of the first or second substrates comprises a glass, glass-ceramic, ceramic, or metal. In additional embodiments, both the first and second substrates comprise a glass or glass-ceramic.

Glasses that have been chemically strengthened by ion exchange may be suitable as substrates according to some non-limiting embodiments. In various embodiments, the first and/or second substrates may comprise chemically strengthened glass having a compressive stress greater than about 100 MPa and a depth of layer of compressive stress (DOL) greater than about 10 microns. According to further embodiments, the first and/or second glass substrates may have a compressive stress greater than about 500 MPa and a DOL greater than about 20 microns, or a compressive stress greater than about 700 MPa and a DOL greater than about 40 microns. Non-limiting examples of suitable commercially available glass substrates include EAGLE XG®, Lotus™, Willow®, Iris™, and Gorilla® glasses from Corning Incorporated, to name a few.

In additional embodiments, the first and/or second substrate can comprise a laminate, for instance, glass/glass, glass-ceramic/glass-ceramic, glass/glass-ceramic, glass/metal, glass-ceramic/metal, glass/ceramic, or glass-ceramic/ceramic laminates. The laminate may, in certain embodiments, include two or more layers having the same or different CTEs. For example, a first layer in the laminate may have a first CTE₁ and a second layer in the laminate may have a second CTE₂, and CTE₁≈CTE₂ or CTE₁>CTE₂ or CTE₁<CTE₂. Of course, laminates comprising more than two layers can also be used, these layers having the same or different CTE.

According non-limiting embodiments, the first and/or second substrates can have a thickness of less than or equal to about 5 mm, for example, ranging from about 0.1 mm to about 4 mm, from about 0.2 mm to about 3 mm, from about 0.3 mm to about 2 mm, from about 0.3 mm to about 1.5 mm, from about 0.4 mm to about 1 mm, from about 0.5 mm to about 0.8 mm, or from about 0.6 mm to about 0.7 mm, including all ranges and subranges therebetween. According to various embodiments, the first and/or second substrates can be chosen from glass substrates having a thickness ranging from about 0.1 mm to about 3 mm, such as from about 0.3 mm to about 2 mm, or from about 0.5 mm to about 1 mm, including all ranges and subranges therebetween. The thickness of the inorganic film 130 can also vary depending on the application and, in certain embodiments, can range from about 10 nm to about 100 μm, such as from about 100 nm to about 50 μm, from about 200 nm to about 10 μm, from about 300 nm to about 5 μm, from about 400 nm to about 2 μm, from about 500 nm to about 1 μm, from about 600 nm to about 900 nm, or from about 700 nm to about 800 nm, including all ranges and subranges therebetween. In certain embodiments, the inorganic film thickness may be less than about 2 μm, such as less than about 1 μm.

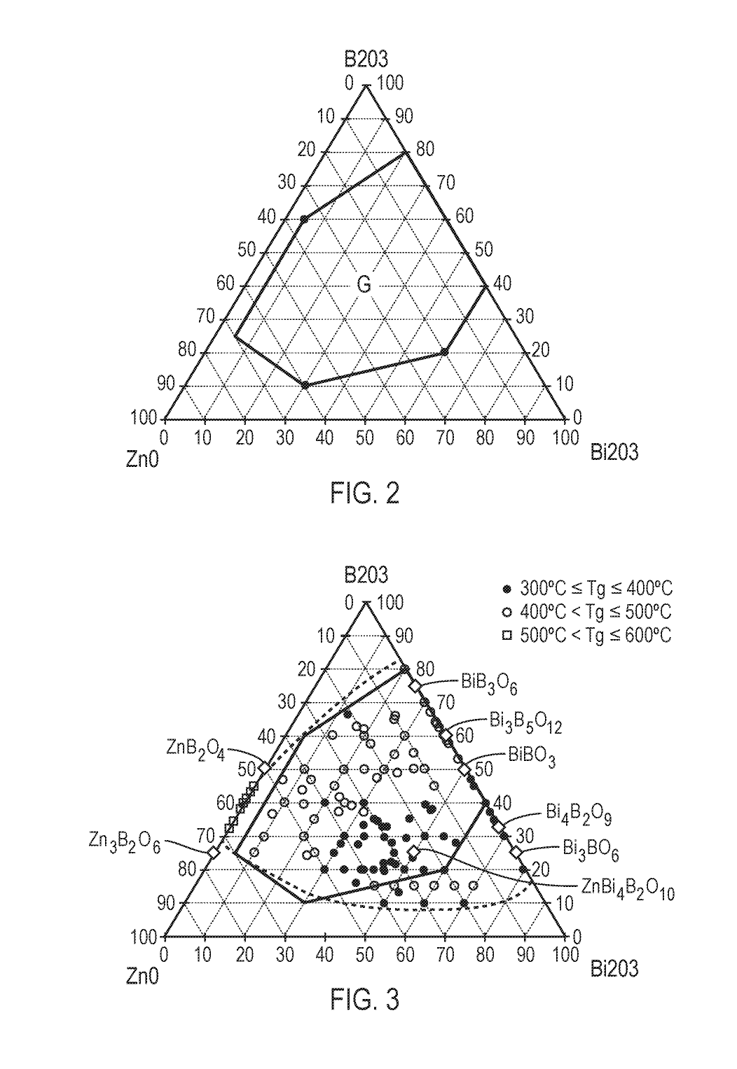

The inorganic film 130 can be chosen, for example, from glasses in the B₂O₃—ZnO—Bi₂O₃ ternary depicted in FIG. 2. In some embodiments, exemplary glasses can have any composition falling within the demarcated region G, e.g., expressed in terms of the respective molar concentrations of B₂O₃, ZnO, and Bi₂O₃. Suitable glasses can include, in some embodiments, about 10-80 mol % B₂O₃, about 5-60 mol % Bi₂O₃, and about 0-70 mol % ZnO. In additional embodiments, the inorganic film can include about 20-65 mol % B₂O₃, about 10-50 mol % Bi₂O₃, and about 0-55 mol % ZnO. In further embodiments, the inorganic film can include about 30-50 mol % B₂O₃, about 15-40 mol % Bi₂O₃, and about 1-40 mol % ZnO. In still further embodiments, the inorganic film can include about 35-45 mol % B₂O₃, about 20-30 mol % Bi₂O₃, and about 5-30 mol % ZnO. In non-limiting embodiments, the inorganic film can include about 40-75 mol % B₂O₃, about 20-45 mol % Bi₂O₃, and about 0-40 mol % ZnO. Combinations and sub-combinations of the compositions given above can also be used. Additional non-limiting film compositions are provided in Table I below.

The inorganic film compositions disclosed herein can optionally include one or more dopants, including but not limited to cerium, niobium, tungsten, iron, vanadium, and combinations thereof. Such dopants, if included, can affect, for example, the optical properties of the inorganic film, and can be used to control the absorption of laser radiation by the inorganic film. In some embodiments, the inorganic film can sufficiently absorb laser radiation at the predetermined wavelength and can be free or substantially free of dopants. As used herein, “substantially free” is intended to denote a concentration of less than about 0.1 mol %, such as less than about 0.05 mol %, less than about 0.01 mol %, or even less than 0.01%. In other embodiments, the inorganic film compositions can optionally include from about 0.1-10 mol % of dopants, such as about 1-8 mol %, about 2-7 mol %, about 3-6 mol %, or about 4-5 mol %, including all ranges and subranges therebetween. According to various embodiments, the inorganic film composition can consist essentially of: about 10-80 mol % B₂O₃, about 5-60 mol % Bi₂O₃, about 0-70 mol % ZnO, and optionally at least one additional oxide of cerium, niobium, tungsten, iron, and/or vanadium, e.g., about 0.1-10 mol % of additional oxide(s). In other embodiments, the inorganic film composition may consist essentially of: about 10-80 mol % B₂O₃, about 5-60 mol % Bi₂O₃, and about 0-70 mol % ZnO. As will be appreciated, the various compositions disclosed herein may refer to the composition of the deposited film or to the composition of the source sputtering target.

In some exemplary embodiments, the inorganic film can be a non-frit glass composition. As used herein, a “non-frit” inorganic film is intended to refer to a non-particulate film that is free or substantially free of inorganic fillers. Exemplary negative CTE (or low expansion) inorganic fillers can include, for instance, cordierite, quartz, silica, alumina, zirconia, silicate (e.g., zirconium silicate), phosphate (e.g., zirconium phosphate), eucryptite, vanadate, and tungstate fillers, to name a few. The inorganic film may also, in some embodiments, be free or substantially free of organic binders. In further embodiments, the inorganic film composition may be free or substantially free of both inorganic fillers and organic binders. According to still further embodiments, the inorganic film can comprise sub-micron particulates, e.g., glass particles having a particle size ranging from about 10 nm to about 1000 nm, but can be free or substantially free of inorganic fillers and/or organic binders.

While glasses comprising B₂O₃, ZnO, and/or Bi₂O₃ have been used as frit sealing compositions, such compositions include glass particles combined with fillers for reducing the CTE mismatch between the sealing composition and the substrates and/or additional components for improving the bond between the sealing composition and the substrates. However, Applicants have surprisingly discovered that inorganic films (e.g., non-frit films) of B₂O₃—ZnO—Bi₂O₃ ternary glasses may be deposited thinly enough to negate the impact of any CTE mismatch, such that the use of fillers can be avoided.

Furthermore, the sealing methods disclosed herein in combination with the disclosed inorganic film compositions may provide sufficient laser absorption to create a strong bond between the two substrates without additional absorbing or auxiliary elements or oxides. For instance, the inorganic film may be free or substantially free of one or more of the following elements and/or oxides thereof: Fe, Cr, Mn, Co, Ni, Cu, Na, La, C, Sn, Cd, and V. In other embodiments, the inorganic film may also be free or substantially free of environmentally hazardous elements, for instance, lead, alkali metals, and/or halides, such as fluorine and chlorine.

The inorganic film compositions disclosed herein may have a relatively low glass transition temperature (Tg). By way of non-limiting example, the inorganic film 130 can comprise a glass with a Tg of less than or equal to about 600° C., such as less than or equal to about 500° C., about 450° C., about 400° C., about 350° C., about 300° C., about 250° C., or about 200° C., e.g., ranging from about 200° C. to about 600° C., or ranging from about 300° C. to about 500° C., including all ranges and subranges therebetween. FIG. 3 depicts the B₂O₃—ZnO—Bi₂O₃ ternary phase diagram with exemplary compositions plotted along with their respective Tg ranges. The glass forming region is demarcated by the dashed line and various crystalline phases are demarcated by open diamonds. Compositions with 300° C.≤Tg≤400° C. are demarcated by solid circles, 400° C.<Tg≤500° C. are demarcated by open circles, and 500° C.<Tg≤600° C. are demarcated by open squares. In some embodiments, the Tg of the compositions may be less than or equal to about 400° C., such as ranging from about 200° C. to about 400° C. or from about 300° C. to about 400° C. In other embodiments, the Tg of the compositions may be greater than about 400° C., or even greater than 500° C., such as ranging from about 400° C. to about 600° C. or from about 500° C. to about 600° C. In further embodiments, the Tg of the compositions may range from about 300° C. to about 500° C. Non-limiting compositions and the Tg for some of these compositions are listed in Table I below.

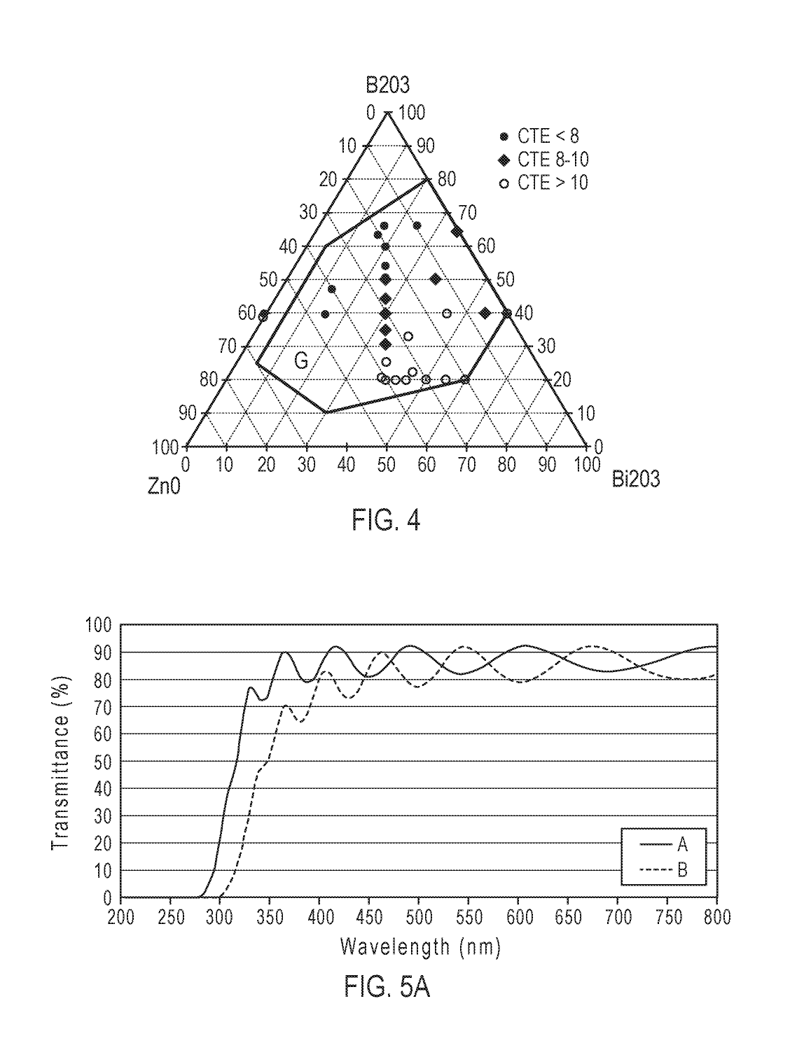

The coefficient of thermal expansion (CTE) of the glasses disclosed herein can vary, e.g., depending on the composition, as illustrated by FIG. 4. For instance, CTE may decrease with decreasing amounts of Bi₂O₃ and/or increasing amounts of ZnO. Compositions with CTE<8×10⁻⁶/° C. are demarcated by solid circles, CTE=8-10 are demarcated by solid diamonds, and CTE>10 are demarcated by open circles. In some embodiments, the CTE of the compositions may be less than or equal to about 8×10⁻⁶/° C., such as ranging from about 4-8×10⁻⁶/° C. or about 5-7×10⁻⁶/° C. or about 6-8×10⁻⁶/° C. In additional embodiments, the CTE of the compositions may be greater than about 8×10⁻⁶/° C., such as ranging from about 8-12×10⁻⁶/° C. or about 9-11×10⁻⁶/° C. or about 8-10×10⁻⁶/° C. In further embodiments, the CTE of the glass compositions may be about 10×10⁻⁶/° C. or less, e.g., ranging from about 4-10×10⁻⁶/° C.

According to exemplary embodiments, the CTE of the inorganic film may be the same or different from that of the first and/or second substrate. For example, the first and/or second substrate may have a first CTEₛ and the inorganic film may have a second CTEᵢ, and CTEₛ≈CTEᵢ or CTEₛ>CTEᵢ or CTEₛ<CTEᵢ. In some embodiments, a difference between CTEᵢ and CTEₛ may be greater than or equal to about 1×10⁻⁶/° C., such as greater than about 2×10⁻⁶/° C., greater than about 3×10⁻⁶/° C., or greater than about 4×10⁻⁶/° C., e.g., ranging from about 1-4×10⁻⁶/° C. According to additional embodiments a ration of CTEₛ:CTEᵢ can range from about 2:1 to about 1:2, such as from about 1.8:1 to about 1:1.8, from about 1.6:1 to about 1:1.6, from about 1.5:1 to about 1:1.5, from about 1.4:1 to about 1:1.4, from about 1.3:1 to about 1:1.3, or from about 1.1:1 to about 1:1.1, including all ranges and subranges therebetween. It should be noted that the CTE values provided herein are measured over a temperature range from about 25-300° C. Non-limiting compositions and the CTE for some of these compositions are listed in Table I below.

In some embodiments, the inorganic film material can be chosen from those having an optical absorbance at the laser's operating wavelength (at room temperature) of greater than about 15%, greater than about 20%, greater than about 25%, greater than about 30%, greater than about 35%, greater than about 40%, greater than about 45%, or greater than about 50%. In further embodiments, the inorganic film can have a UV cutoff of about 380 nm or less, such as ranging from about 340-380 nm or from about 360-380 nm. UV “cutoff” can be defined as the wavelength at which optical transmittance rises above a specified limit (or, conversely, at which optical absorbance drops above a specified limit), for instance, greater than about 70% transmittance (corresponding roughly to about 15% or less absorbance). Transmittance (T) and absorbance (A) of light emitting from a sample can be correlated by the following equations:

A=−log(T)

T=10^{-A}.

For example, about 20% transmittance is about 70% absorbance, about 50% transmittance is about 30% absorbance, and about 80% transmittance is about 10% absorbance. As defined herein, unless clearly indicated otherwise, UV cutoff is intended to denote the wavelength at which optical absorbance drops below about 15%. Non-limiting compositions and the UV cutoff for some of these compositions are listed in Table I below.

TABLE I
Exemplary B₂O₃—ZnO—Bi₂O₃ Ternary Compositions

| Compo- | B₂O₃ | Bi₂O₃ | ZnO | UV cutoff* | Tg | CTE |
|---|---|---|---|---|---|---|
| sition | (mol %) | (mol %) | (mol %) | (nm) | (° C.) | (×10⁻⁶/° C.) |
| 1 | 64.27 | 35.54 | 0.20 | 364 | 446.1 | 8.53 |
| 2 | 65.93 | 24.75 | 9.31 | 354 | 458.3 | 7.70 |
| 3 | 62.09 | 18.84 | 19.08 | 344 | | |
| 4 | 53.11 | 16.56 | 20.33 | | 481.1 | 6.41 |
| 5 | 50.46 | 49.44 | 0.10 | 390 | 398.1 | 9.75 |
| 6 | 50.11 | 37.48 | 12.40 | 378 | 426.8 | 8.96 |
| 7 | 49.92 | 25.14 | 24.94 | 364 | 452.3 | 7.99 |
| 8 | 40.57 | 59.24 | 0.19 | | 425.9 | |
| 9 | 39.76 | 45.25 | 14.99 | 340 | 388.9 | 10.25 |
| 10 | 40.02 | 30.03 | 29.95 | | 421.2 | 9.00 |
| 11 | 36.72 | 8.70 | 54.58 | 396 | 466.4 | |
| 12 | 46.84 | 13.27 | 39.90 | 354 | 473.2 | 6.63 |
| 13 | 39.56 | 15.12 | 45.32 | 360 | 462.9 | 6.66 |
| 14 | 40.00 | 5000 | 10.00 | | 371.0 | |
| 15 | 40.00 | 40.00 | 20.00 | | 391.0 | |
| 16 | 40.00 | 30.00 | 30.00 | | 406.0 | |
| 17 | 55.00 | 45.00 | 0.00 | 292 | 448.0 | |
| 18 | 75.00 | 25.00 | 0.00 | 272 | 455.0 | |
| 19 | 40.00 | 20.00 | 40.00 | 270 | 458.0 | |
| 20 | 40.00 | 40.00 | 20.00 | 282 | 436.0 | |
| 21 | 40.00 | 20.00 | 40.00 | | 458.0 | |
| 22 | 40.00 | 40.00 | 20.00 | | 436.0 | |
| 23 | 60.34 | 39.66 | 0.00 | 307 | 422.0 | |
| 24 | 60.35 | 29.70 | 995 | 292 | 456.0 | |
| 25 | 60.15 | 19.75 | 20.11 | 272 | 475.0 | |
| 26 | 50.55 | 39.48 | 9.97 | 305 | 413.0 | |
| 27 | 50.22 | 29.73 | 20.05 | 298 | 445.0 | |
| 28 | 55.58 | 39.42 | 5.01 | 307 | 434.0 | |
| 29 | 55.31 | 29.79 | 14.90 | 291 | 452.0 | |
| 30 | 55.37 | 20.19 | 24.44 | 278 | 470.0 | |
| 31 | 63.10 | 16.60 | 20.30 | | 480.0 | 6.41 |
| 32 | 49.90 | 25.10 | 24.90 | | 452.8 | 7.99 |
| 33 | 40.00 | 30.00 | 30.00 | | 420.9 | 9.00 |
| 34 | 44.00 | 28.00 | 28.00 | | 428.1 | 8.61 |
| 35 | 54.00 | 23.00 | 23.00 | | 464.8 | 7.65 |
| 36 | 59.60 | 20.30 | 20.20 | | 476.4 | 7.19 |
| 37 | 65.90 | 16.80 | 17.20 | | 484.9 | 6.89 |
| 38 | 34.60 | 32.60 | 32.80 | | 400.9 | 9.21 |
| 39 | 30.20 | 35.00 | 34.90 | | 387.2 | 9.72 |
| 40 | 40.00 | 40.00 | 20.00 | | 376.0 | |
| 41 | 40.00 | 50.00 | 10.00 | | 377.0 | |
| 42 | 40.00 | 60.00 | 0.00 | | 360.0 | |
| 43 | 30.00 | 40.00 | 30.00 | | 368.0 | |
| 44 | 30.00 | 50.00 | 20.00 | | 358.0 | |
| 45 | 30.00 | 60.00 | 10.00 | | 326.0 | |
| 46 | 20.00 | 40.00 | 40.00 | | 346.0 | |
| 47 | 20.00 | 50.00 | 30.00 | | 344.0 | |
| 48 | 20.00 | 60.00 | 20.00 | | 331.0 | |

*UV cutoff is defined in this table as the wavelength at which the transmission rises above 1%.

At least one of the inorganic film, first substrate, and/or second substrate can, in various embodiments, be transparent or substantially transparent before and/or after sealing. In some embodiments, the sealed device, including the weld or bond region, can be transparent or substantially transparent. As used herein, the term “transparent” is intended to denote that the substrate, film, device, and/or seal has an optical transmittance of greater than or equal to about 80% in the visible region of the spectrum (˜420-750 nm). For instance, an exemplary transparent substrate, film, device, and/or seal may have greater than about 85% optical transmittance in the visible light range, such as greater than about 90%, or greater than about 95%, including all ranges and subranges therebetween.

The first and second substrates can, in various embodiments be sealed together via the inorganic film as disclosed herein to produce a hermetic sealed device. For example, the seal may be a hermetic seal, e.g., forming one or more air-tight and/or waterproof pockets in the device. For instance, the device can be hermetically sealed such that it is impervious or substantially impervious to water, moisture, air, and/or other contaminants. By way of non-limiting example, a hermetic seal can be configured to limit the transpiration (diffusion) of oxygen to less than about 10⁻² cm³/m²/day (e.g., less than about 10⁻³/cm³/m²/day), and limit transpiration of water to about 10⁻² g/m²/day (e.g., less than about 10⁻³, 10⁻⁴, 10⁻⁵, or 10⁻⁶ g/m²/day). In various embodiments, a hermetic seal can substantially prevent water, moisture, and/or air from contacting the components protected by the hermetic seal.

According to certain aspects, the total thickness of the sealed device can be less than about 5 mm, such as less than about 4 mm, less than about 3 mm, less than about 2 mm, less than about 1 mm, less than about 0.5 mm, or less than about 0.1 mm, including all ranges and subranges therebetween. For example, the thickness of the sealed device can range from about 0.1 mm to about 5 mm, such as from about 0.3 mm to about 4 mm, from about 0.5 mm to about 3 mm, or from about 1 mm to about 2 mm, including all ranges and subranges therebetween. The sealed devices disclosed herein may be used as components in various display and electronic devices, or may be used to seal and protect one or more components in a display or electronic device including, but not limited to LDs, LEDs, OLEDs, QDs, phosphors, TCOs, semiconductors, electrodes, conductive leads, and the like.

Methods

Disclosed herein are methods for sealing devices, the methods comprising forming an inorganic film over a surface of a first substrate; positioning a second substrate in contact with the inorganic film; and bonding the first and second substrates by locally heating the inorganic film with laser radiation having a predetermined wavelength, wherein the inorganic film comprises from about 10-80 mol % B₂O₃, from about 5-60 mol % Bi₂O₃, and from about 0-70 mol % ZnO.

The components of the sealed device 100 formed in FIG. 1A can be brought into contact by any means known in the art and may, in certain embodiments, be brought into contact using force, e.g., an applied compressive force, to ensure good contact at the sealing interface. According to various embodiments disclosed herein, the inorganic film 130 may be deposited on the first and/or second substrate 110, 120 using a variety of methods known in the art. For example, deposition may be carried out by sputtering, (e.g., ion-beam sputtering), chemical vapor deposition (CVD), plasma enhanced CVD (PECVD), flame deposition, evaporation, or pyrolysis, to name a few. In various embodiments, these deposition methods may be carried out in an inert environment (e.g., Ar, He, Ne, Kr, Rn, etc.) or in a reactive environment (e.g., O₂, H₂, N₂, etc.). As such, the starting material prior to deposition may have the same composition as the deposited inorganic film (e.g., a glass sputtering target) or a different composition (e.g., inorganic oxide precursor(s)). In some embodiments, deposition may take place in an environment comprising a mixture of inert and reactive gases, such as a mixture of Ar and O₂. Inorganic film compositions comprising bismuth may, in certain embodiments, benefit from added O₂ during deposition to ensure the film stays oxidized and transmissive at visible wavelengths. Exemplary ratios for mixed gas compositions can range from about 1:1 to about 10:1 by volume (inert:reactive, e.g., Ar:O₂), such as from about 2:1 to about 9:1, from about 3:1 to about 8:1, from about 4:1 to about 7:1, or from about 5:1 to about 6:1, including all ranges and subranges therebetween.

In additional embodiments, the inorganic film may be deposited on the first and/or second substrates by dip-coating. For example, a glass having the desired inorganic film composition can be formed by melting and cooling inorganic batch materials. In some embodiments, the glass may be annealed, e.g., at a temperature ranging from about 300° C. to about 600° C., from about 350° C. to about 550° C., or from about 400° C. to about 500° C., including all ranges and subranges therebetween. The resulting glass can subsequently be ground or milled into fine particles and the first and/or second substrates can be dipped into a mixture of such particles to form a film on one or more surfaces thereof. Exemplary particle sizes can include sub-micron particles, such as ranging from about 10 nm to about 1000 nm, from about 50 nm to about 900 nm, from about 100 nm to about 800 nm, from about 200 nm to about 700 nm, from about 300 nm to about 600 nm, or from about 400 nm to about 500 nm, including all ranges and subranges therebetween.

Referring to FIG. 1B, the device 100 may be sealed after assembly, e.g., using a laser 140. For instance, embodiments of the present disclosure provide a laser sealing process that relies upon optical absorption of the inorganic film at an incident laser wavelength, induced optical absorption by one or both of the substrates at the incident laser wavelength, color center formation within the substrates due to impurities, and/or direct optical absorption by intrinsic color centers inherent to the substrates. Welds made using this method can, in some embodiments, utilize materials having sufficient ultraviolet (UV) or near-infrared (NIR) absorption to provide a final product or seal that is transmissive (e.g., transparent) at visible wavelengths.

The laser 140 used to form the seal between the first and second substrates may be chosen from any suitable laser known in the art for substrate welding. For example, the laser may emit light at UV (˜190-410 nm) or NIR (780-5000 nm) wavelengths. In certain embodiments, a continuous wave or pulsed UV laser operating at about 355 nm, or any other suitable UV wavelength, may be used. In further embodiments, a continuous wave or pulsed near-infrared laser operating at about 810 nm, or any other suitable NIR wavelength, may be used. According to various embodiments, the laser may operate at a predetermined wavelength ranging from about 300 nm to about 1600 nm, such as from about 350 nm to about 1400 nm, from about 400 nm to about 1000 nm, from about 450 nm to about 750 nm, from about 500 nm to about 700 nm, or from about 600 nm to about 650 nm, including all ranges and subranges therebetween.

According to various embodiments, the laser 140 can operate at an average power greater than about 3 W, for example, ranging from about 5 W to about 160 W, such as from about 10 W to about 140 W, from about 20 W to about 120 W, from about 30 W to about 100 W, from about 40 W to about 90 W, from about 50 W to about 80 W, or from about 60 W to about 70 W, including all ranges and subranges therebetween. In additional embodiments, the laser can have an average power of less than 3 W, such as ranging from about 0.1 W to about 2 W, from about 0.2 W to about 1.5 W, from about 0.5 W to about 1 W, including all ranges and subranges therebetween. Still further, the laser power can range from about 0.2 W to about 50 W, such as from about 0.5 W to about 40 W, from about 1 W to about 30 W, from about 2 W to about 25 W, from about 3 W to about 20 W, from about 4 W to about 15 W, from about 5 W to about 12 W, from about 6 W to about 10 W, or from about 7 W to about 8 W, including all ranges and subranges therebetween.

The laser 140 may operate at any frequency and may, in certain embodiments, operate in a pulsed, quasi-continuous, or continuous manner. In some non-limiting embodiments, a pulsed laser may have a pulse frequency (repetition rate) ranging from about 1 kHz to about 5 MHz, such as from about 10 kHz to about 3 MHz, from about 50 kHz to about 2 MHz, from about 100 kHz to about 1 MHz, or from about 200 kHz to about 500 kHz, including all ranges and subranges therebetween. According to various embodiments, the laser may operate in burst mode having a plurality of bursts with a burst repetition frequency ranging from about 1 kHz to about 1 MHz, such as from about 10 kHz to about 500 kHz, from about 20 kHz to about 400 kHz, from about 30 kHz to about 300 kHz, from about 40 kHz to about 200 kHz, or from about 50 kHz to about 100 kHz, including all ranges and subranges therebetween.

The duration or pulse width of the laser 140 may vary, for example, the pulse width may be less than about 200 ns in certain embodiments, such as ranging from about 10 ns to about 200 ns, from about 20 ns to about 150 ns, from about 30 ns to about 100 ns, or from about 40 ns to about 50 ns. In other embodiments, the pulse width or duration may be less than about 10 ns, such as less than about 5 ns, less than about 1 ns, less than about 10 ps, or less than about 1 ps. Exemplary lasers and methods for forming glass-to-glass welds and other exemplary seals are described in pending and co-owned U.S. patent application Ser. Nos. 13/777,584, 14/270,827, and 14/271,797, which are each incorporated herein by reference in their entireties.

As shown in FIG. 1B, the laser 140 may be directed at and focused on the sealing interface, below the sealing interface, or above the sealing interface, such that the beam spot diameter D on the interface may be less than about 1 mm. For example, the beam spot diameter may be less than about 500 microns, such as less than about 400 microns, less than about 300 microns, or less than about 200 microns, less than about 100 microns, less than 50 microns, or less than 20 microns, including all ranges and subranges therebetween. In some embodiments, the beam spot diameter D may range from about 10 microns to about 500 microns, such as from about 50 microns to about 250 microns, from about 75 microns to about 200 microns, or from about 100 microns to about 150 microns, including all ranges and subranges therebetween.

The laser 140 may be scanned or translated relative to the substrates (as indicated by the arrow), or the substrates can be translated relative to the laser, using any predetermined path to produce any pattern, such as a square, rectangular, circular, oval, or any other suitable pattern or shape, for example, to hermetically or non-hermetically seal one or more cavities in the device. The translation speed V at which the laser beam (or substrate) moves along the predetermined path may vary by application and may depend, for example, upon the composition of the first and second substrates and/or the focal configuration and/or the laser beam power, frequency, and/or wavelength. In certain embodiments, the laser may have a translation speed ranging from about 1 mm/s to about 1000 mm/s, for example, from about 10 mm/s to about 500 mm/s, or from about 50 mm/s to about 700 mm/s, such as greater than about 100 mm/s, greater than about 200 mm/s, greater than about 300 mm/s, greater than about 400 mm/s, greater than about 500 mm/s, or greater than about 600 mm/s, including all ranges and subranges therebetween.

The average amount of time the laser beam spends on a single weld spot, also referred to as the “dwell time,” can be correlated to both the spot diameter D and the translation speed V, e.g., dwell time=(D/V). Exemplary dwell times can range, for example, from about 1 microsecond (ms) to about 10 ms, such as from about 2 ms to about 9 ms, from about 3 ms to about 8 ms, from about 4 ms to about 7 ms, or from about 5 ms to about 6 ms, including all ranges and subranges therebetween.

The translation speed V and spot diameter D of the laser beam at the sealing interface may affect the strength, pattern, and/or morphology of the laser weld. Additionally, the repetition rate (rₚ) for a pulsed laser or the modulation rate (rₘ) for a continuous wave (CW) laser can affect the resulting laser weld line. In certain embodiments, a pulsed laser may be operated at a translation speed V that is greater than the product of the spot diameter D of the laser beam at the sealing interface and the repetition rate of the laser beam (rₚ), according to formula (1):

V/(D*rₚ)>1 (1)

Similarly, a modulated CW laser can be operated at a translation speed V that is greater than the product of the spot diameter D of the laser beam at the sealing interface and the modulation rate of the laser beam (rₘ), according to formula (1′):

V/(D*rₘ)>1 (1′)

Of course, for a given translation speed, the spot diameter, repetition rate, and/or modulation rate can also be varied to satisfy formulae (1) or (1′). A laser operating under these parameters can produce a non-overlapping laser weld comprising individual “spots.” For instance, the time between laser pulses (1/rₚ or 1/rₘ) can be greater than the dwell time (D/V). In some embodiments, V/(D*rₚ) or V/(D*rₘ) can range from about 1.05 to about 10, such as from about 1.1 to about 8, from about 1.2 to about 7, from about 1.3 to about 6, from about 1.4 to about 5, from about 1.5 to about 4, from about 1.6 to about 3, from about 1.7 to about 2, or from about 1.8 to about 1.9, including all ranges and subranges therebetween. Such a weld pattern may be used, for example, to produce a non-hermetic seal according to various embodiments of the disclosure.

In other embodiments, a pulsed laser may be operated at a translation speed V that is less than or equal to the product of the spot diameter D and the repetition rate (rₚ), according to formula (2):

V/(D*rₚ)≤1 (2)

Similarly, a modulated CW laser can be operated at a translation speed V that is less than or equal to the product of the spot diameter D of the laser beam at the sealing interface and the modulation rate of the laser beam (rₘ), according to the following formula (2′):

V/(D*rₘ)≤1 (2′)

Of course, for a given translation speed, the spot diameter, repetition rate, and/or modulation rate can also be varied to satisfy formulae (2) or (2′). Operating under such parameters can produce an overlapping laser weld comprising contiguous “spots” that can approach a continuous line (e.g., as rₘ or rₚ increase to infinity). For instance, the time between laser pulses (1/rₚ or 1/rₘ) can be less than or equal to the dwell time (D/V). In some embodiments, V/(D*rₚ) or V/(D*rₘ) can range from about 0.01 to about 1 such as from about 0.05 to about 0.9, from about 0.1 to about 0.8, from about 0.2 to about 0.7, from about 0.3 to about 0.6, or from about 0.4 to about 0.5, including all ranges and subranges therebetween. These weld patterns may be used, for example, to produce a hermetic seal according to various embodiments of the disclosure.

According to various embodiments disclosed herein, the laser wavelength, pulse duration, repetition rate, average power, focusing conditions, dwell time, and other relevant parameters may be varied to produce sufficient energy to weld the first and second substrates together by way of the thin inorganic film. It is within the ability of one skilled in the art to vary these parameters as necessary for a desired application.

The sealing methods disclosed herein can produce bonds or welds having varying widths. The sealing material (e.g., inorganic film) composition and/or properties can also affect the resulting weld width. For instance, inorganic films with greater optical absorbance at the laser operating wavelength may produce wider welds than less absorbing films. In some embodiments, the weld width can range from about 50 μm to about 1 mm, such as from about 100 μm to about 800 μm, from about 200 μm to about 700 μm, from about 300 μm to about 600 μm, or from about 400 μm to about 500 μm, including all ranges and subranges therebetween.

Embodiments of the disclosure are further illustrated by the following Examples, which are intended to be non-restrictive and illustrative only, with the scope of the invention being defined by the claims.

### Examples

Experimental Method

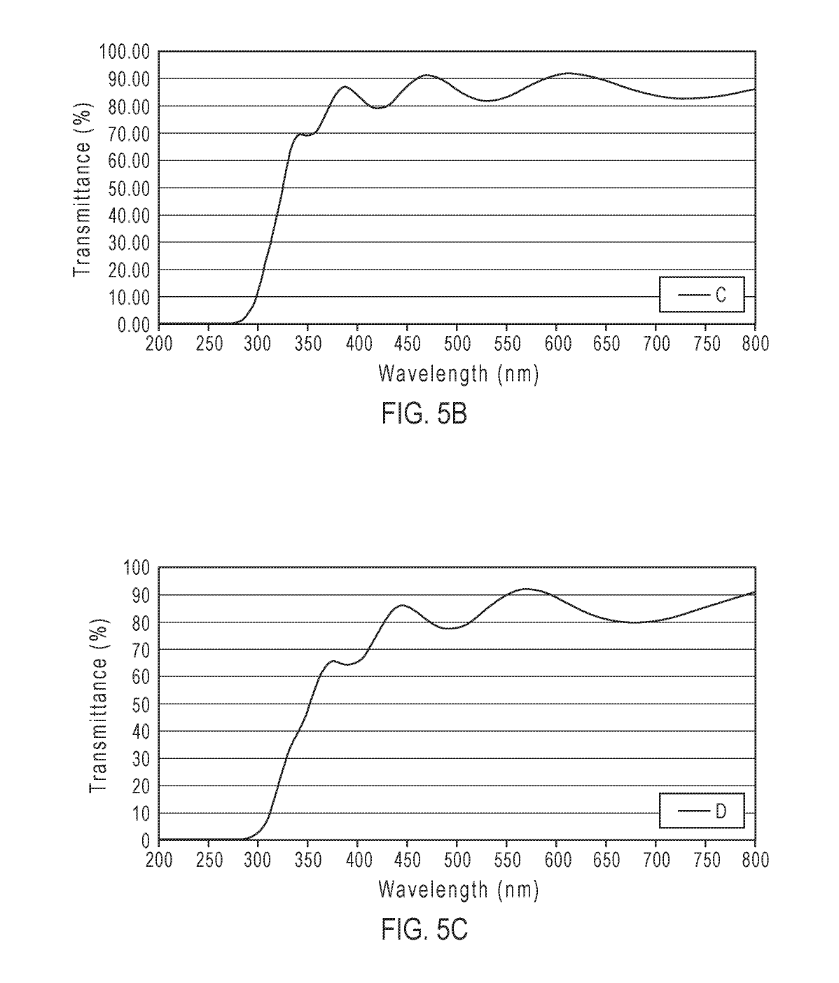

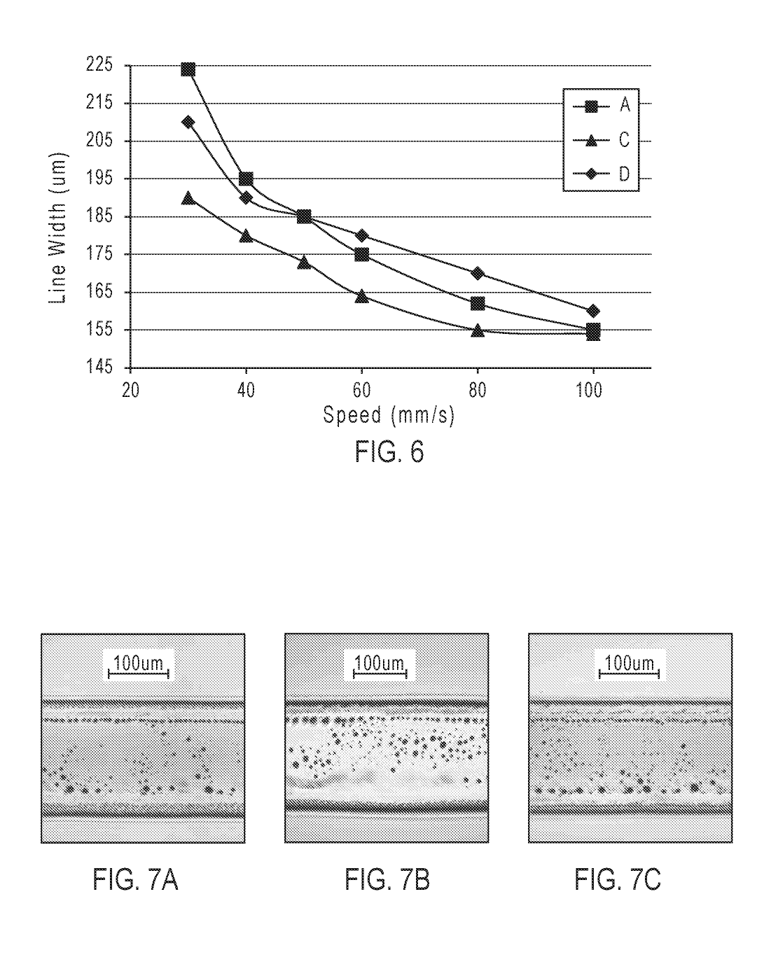

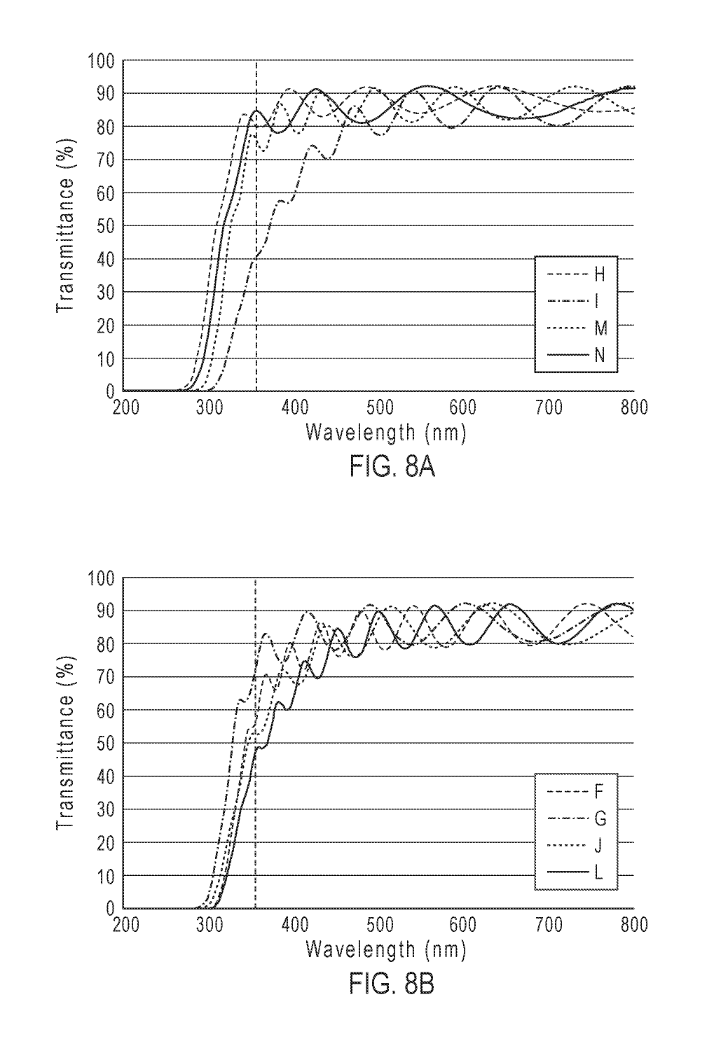

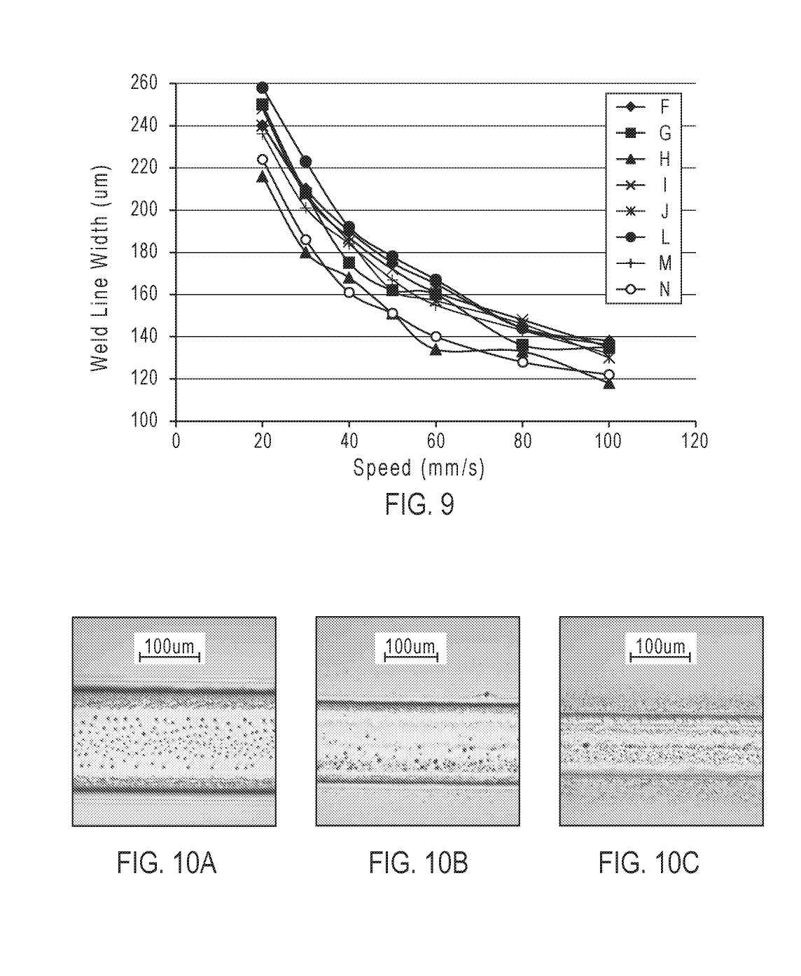

The batch materials listed in Tables II and IV below were weighed, mixed, and subsequently melted for 1 hour at 900° C. (Compositions A-D) or 2 hours at 1100° C. (Compositions F-N) in covered silica crucibles, annealed at 550° C., and slowly cooled to room temperature. The Tg of the resulting compositions was measured and is listed in Tables II and V. Sputtering targets (3″ diameter) were prepared by either drilling a core in the glass or by grinding the glass and packing the resulting powder. The targets were sputtered using Ar with added O₂ onto a 2″×2″ Corning EAGLE XG® substrate using the parameters set forth in Tables III and V. The film thickness was measured and is listed in Tables III and V. Optical transmittance for films sputtered in a 2:1 Ar/O₂ environment at a power of 50 W for 6 hours is plotted in FIGS. 5A-C(Compositions A-D). Optical transmittance for 0.7 mm thick glass samples is plotted in FIGS. 8A-B (Compositions F-N). A second 2″×2″ EAGLE XG® substrate was brought into contact with the sputtered film and the two substrates were sealed together using a 355 nm UV nanosecond pulsed laser operating at 5.4 W, with laser scan speeds ranging from 30-100 mm/s. The strength and durability of the resulting seals was analyzed and the laser weld width measured. Weld width as a function of laser scan speed is plotted in FIGS. 6 and 9. Photographs of exemplary glass welds are illustrated in FIGS. 7A-C and 10A-C.

TABLE II
B₂O₃—ZnO—Bi₂O₃ Ternary Compositions A-D

| | | | | Tg | Tg |
|---|---|---|---|---|---|
| Compo- | | | | onset | peak |
| sition | B₂O₃ | Bi₂O₃ | ZnO | (° C.) | (° C.) |
| A | 15.44 wt % | 84.56 wt % | 0 wt % | 448 | 462 |
| | (55 mol %) | (45 mol %) | (0 mol %) | | |
| B | 30.95 wt % | 69.05 wt % | 0 wt % | 455 | 468 |
| | (75 mol %) | (25 mol %) | (0 mol %) | | |
| C | 18.13 wt % | 60.68 wt % | 21.19 wt % | 458 | 470 |
| | (40 mol %) | (20 mol %) | (40 mol %) | | |
| D | 12.08 wt % | 80.86 wt % | 7.06 wt % | 436 | 449 |
| | (40 mol %) | (40 mol %) | (20 mol %) | | |

TABLE III
Sputtering Conditions and Film Thickness for Compositions A-D

| Compo- | | Power | Ar/O₂ | Time | Thickness |
|---|---|---|---|---|---|
| sition | Target* | (W) | (sccm) | (hr) | (nm) |
| A | PP | 50 | 20/10 | 6 | ~520 |
| A | PP | 50 | 20/10 | 6 | ~640 |
| B | PP | 50 | 20/10 | 6 | ~737 |
| C | PP | 50 | 20/0 | 6 | 575 |
| C | PP | 50 | 20/10 | 6 | ~490 |
| C | PP | 50 | 20/10 | 6 | ~425 |
| D | PP | 50 | 20/0 | 4.25 | 360 |
| D | PP | 50 | 20/10 | 4.25 | 455 |
| D | PP | 50 | 20/5 | 4.25 | 440 |
| D | PP | 50 | 20/10 | 4.25 | ~340 |

*PP = packed glass powder target

TABLE IV
B₂O₃—ZnO—Bi₂O₃ Ternary Compositions F-N

| | | | | Tg | Tg |
|---|---|---|---|---|---|
| Compo- | | | | onset | peak |
| sition | B₂O₃ | Bi₂O₃ | ZnO | (° C.) | (° C.) |
| F | 18.5 wt % | 81.4 wt % | 0 wt % | 422 | 432 |
| | (60.34 mol %) | (39.66 mol %) | (0 mol %) | | |
| G | 22.1 wt % | 72.8 wt % | 4.26 wt % | 456 | 467 |
| | (60.35 mol %) | (29.70 mol %) | (9.95 mol %) | | |
| H | 27.9 wt % | 61.3 wt % | 10.9 wt % | 475 | 489 |
| | (60.15 mol %) | (19.75 mol %) | (20.11 mol %) | | |
| I | 15.4 wt % | 80.5 wt % | 3.55 wt % | 413 | 426 |
| | (50.55 mol %) | (39.48 mol %) | (9.97 mol %) | | |
| J | 18.3 wt % | 72.5 wt % | 8.54 wt % | 445 | 456 |
| | (50.22 mol %) | (29.73 mol %) | (20.05 mol %) | | |
| K | 22.8 wt % | 61.1 wt % | 16.0 wt % | * | * |
| | (50 mol %) | (20 mol %) | (30 mol %) | | |
| L | 17.0 wt % | 80.7 wt % | 1.79 wt % | 434 | 443 |
| | (55.58 mol %) | (39.42 mol %) | (5.01 mol %) | | |
| M | 20.2 wt % | 72.8 wt % | 6.36 wt % | 452 | 463 |
| | (55.31 mol %) | (29.79 mol %) | (14.90 mol %) | | |
| N | 25.2 wt % | 61.5 wt % | 13.0 wt % | 470 | 484 |
| | (55.37 mol %) | (20.19 mol %) | (24.44 mol %) | | |

* Composition K was contaminated by the silica crucible and further measurements were not made

TABLE V
Sputtering Conditions and Film Thickness for Compositions F-N

| Compo- | | Power | Ar/O₂ | Time | Thickness |
|---|---|---|---|---|---|
| sition | Target* | (W) | (sccm) | (hr) | (nm) |
| F | PP | 50 | 20/10 | 6.7 | ~954 |
| G | PP | 50 | 20/10 | 6 | ~540 |
| H | GC | 50 | 20/10 | 6 | ~492 |
| I | GC | 50 | 20/10 | 6.2 | ~842 |
| J | GC | 50 | 20/10 | 6 | ~640 |
| L | GC | 50 | 20/10 | 6 | ~984 |
| M | GC | 50 | 20/10 | 6 | ~731 |
| N | PP | 50 | 20/10 | 6 | ~430 |

*PP = packed glass powder target; GC = glass core

Analysis

Referring to FIGS. 5A-C and 8A-B, the transmittance spectra show that Compositions A-D, F-J, and L-N generally exhibit greater than 70% or even greater than 80% optical transmittance for light in the visible range (˜420-750 nm). While there is some variance in the data, it is believed that such variance may be due to oxidation and/or reduction of Bi₂O₃ during melting and/or sputtering, which may lead to a slight coloration of the inorganic film (e.g., composition I had a slight yellow tint). While the transmittance of the films was measured before sealing, it is to be understood that the transparency of the resulting seal may change during the welding process, for instance, transparency may increase or decrease, or it may stay the same.

Referring to FIGS. 6 and 9, it was noted that inorganic films with lower optical transmittance (higher optical absorbance) at the laser operating wavelength (355 nm) generally resulted in wider weld lines. Moreover, higher laser scan speeds generally resulted in narrower weld lines. FIGS. 7A-C illustrate exemplary welds made using inorganic films of Compositions D, A, and C, respectively, at a laser scan speed of 30 mm/s. It is believed the black spots in the weld area may be voids or air bubbles. Wider weld lines were observed for compositions with lower transmittance (e.g., A>D>C). FIGS. 10A-C illustrate exemplary welds made using an inorganic film of Composition J at laser scan speeds ranging from 20-100 mm/s, and further illustrate wider weld lines for lower laser scan speeds (e.g., 240 μm (20 mm/s)>160 μm (50 mm/s)>130 μm (100 mm/s)). Finally, each combination of scan speed and composition appeared to result in a suitable weld having a width (e.g., greater than 50 μm) sufficient to maintain the strength and durability of the seal.

It will be appreciated that the various disclosed embodiments may involve particular features, elements or steps that are described in connection with that particular embodiment. It will also be appreciated that a particular feature, element or step, although described in relation to one particular embodiment, may be interchanged or combined with alternate embodiments in various non-illustrated combinations or permutations.

It is also to be understood that, as used herein the terms “the,” “a,” or “an,” mean “at least one,” and should not be limited to “only one” unless explicitly indicated to the contrary. Thus, for example, reference to “a weld” includes examples having two or more such welds unless the context clearly indicates otherwise. Likewise, a “plurality” or an “array” is intended to denote “more than one.” As such, a “plurality” or “array” of welds includes two or more such welds, such as three or more such welds, etc.

Ranges can be expressed herein as from “about” one particular value to another particular value. When such a range is expressed, examples include from the one particular value and/or to the other particular value, as well as “about” both particular values. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

The terms “substantial,” “substantially,” and variations thereof as used herein are intended to note that a described feature is equal or approximately equal to a value or description. For example, a “substantially planar” surface is intended to denote a surface that is planar or approximately planar. Moreover, “substantially similar” is intended to denote that two values are equal or approximately equal.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred.

While various features, elements or steps of particular embodiments may be disclosed using the transitional phrase “comprising,” it is to be understood that alternative embodiments, including those that may be described using the transitional phrases “consisting” or “consisting essentially of,” are implied. Thus, for example, implied alternative embodiments to a device that comprises A+B+C include embodiments where a device consists of A+B+C and embodiments where a device consists essentially of A+B+C.

It will be apparent to those skilled in the art that various modifications and variations can be made to the present disclosure without departing from the spirit and scope of the disclosure. Since modifications combinations, sub-combinations and variations of the disclosed embodiments incorporating the spirit and substance of the disclosure may occur to persons skilled in the art, the disclosure should be construed to include everything within the scope of the appended claims and their equivalents.

1-35. (canceled)

36. A sealed device comprising:
an inorganic film formed over a surface of a first substrate;
a second substrate in contact with the inorganic film; and
a bond formed between the inorganic film and the first and second substrates,
wherein the inorganic film comprises from about 10-80 mol % B₂O₃, from about 5-60 mol % Bi₂O₃, and from about 0-70 mol % ZnO.

37. The sealed device of claim 36, wherein the inorganic film, and optionally the first or second substrate, has an optical transmittance of at least about 80% at approximately 420-750 nm.

38. The sealed device of claim 36, wherein the inorganic film has an optical absorbance of at least about 15% at a predetermined laser wavelength.

39. The sealed device of claim 38, wherein the predetermined laser wavelength is an ultraviolet wavelength ranging from approximately 190-410 nm.

40. The sealed device of claim 36, wherein the inorganic film does not comprise one or more elements selected from the group consisting of Fe, Cr, Mn, Co, Ni, Cu, Na, La, C, Sn, Cd, and V.

41. The sealed device of claim 36, wherein the inorganic film is substantially free of inorganic fillers.

42. The sealed device of claim 36, wherein the inorganic film comprises a non-frit glass composition.

43. The sealed device of claim 36, wherein the inorganic film comprises:
40-75 mol % B₂O₃;
20-45 mol % Bi₂O₃; and
0-40 mol % ZnO.

44. The sealed device of claim 36, wherein the inorganic film consists essentially of:
10-80 mol % B₂O₃;
5-60 mol % Bi₂O₃;
0-70 mol % ZnO; and optionally at least one oxide of Ce, Nb, W, Fe, or V.

45. The sealed device of claim 36, wherein the inorganic film has a thickness ranging from about 10 nm to about 2 μm.

46. The sealed device of claim 36, wherein the inorganic film has a glass transition temperature ranging from about 300-500° C.

47. The sealed device of claim 36, wherein the inorganic film has a coefficient of thermal expansion of about 4-12×10⁻⁶1° C. over a temperature range of about 25-300° C.

48. The sealed device of claim 36, wherein the inorganic film has a coefficient of thermal expansion different from a coefficient of thermal expansion of the first or second substrate.

49. The sealed device of claim 36, wherein the inorganic film has a UV cutoff at about 380 nm or less.

50. The sealed device of claim 36, wherein at least one of the first and second substrates comprises a glass, glass-ceramic, ceramic, or metal.

51. The sealed device of claim 36, wherein both the first and second substrates comprise a glass or glass-ceramic.

52. The sealed device of claim 36, further comprising a device positioned between the first and second substrates, wherein the device is selected from the group consisting of laser diodes, light emitting diodes, organic light emitting diodes, conductive leads, transparent conductive oxide layers, semiconductors, electrodes, quantum dot materials, phosphors, and combinations thereof.

53. A display device comprising the sealed device of claim 36.
